(19) United States
(12) Patent Application Publication
(10) Pub. No.: US 2019/0110380 A1
(43) Pub. Date: Apr. 11, 2019

(54) COOLING SYSTEM AND METHODS OF ASSEMBLING THE SAME

(71) Applicant: GENERAL ELECTRIC COMPANY, Schenectady, NY (US)

(72) Inventors: Mark Aaron Chan Chan, Munich (DE); Andrew Peter Goldney, Northhamptonshire (GB)

(21) Appl. No.: 16/300,374

(22) PCT Filed: May 20, 2016
(86) PCT No.: PCT/US2016/033488

§ 371 Date: Nov. 9, 2018

(51) Int. Cl. H05K 7/20

(52) U.S. Cl. CPC H05K 7/20936; H05K 7/20363

(57) ABSTRACT

An electrical system for use in powering an electrical device includes a housing, a plurality of electrical components positioned within the housing, and a cooling system coupled in flow communication with the plurality of electrical components. The cooling system includes a sorption chiller positioned proximate the housing and is configured to utilize waste heat from the plurality of electrical components to condition air within the housing such that an internal temperature of the housing is less than an ambient temperature external to the housing.

### BACKGROUND

The field of disclosure relates generally to cooling systems, and more particularly, to cooling systems used to cool electrical components within a housing.

At least some known devices include electrical components that facilitate providing power to or controlling the device. For example, electrical power converters are devices that convert electrical energy from one form to another, from AC to DC, or change the frequency or voltage. Power converters are used across a wide range of industries, for example, solar energy, wind power, electric vehicles, marine propulsion, pumps or compressor drives, etc. At least some known power converters incur energy losses in the form of heat dissipation. A majority of the heat is dissipated through the electronic switches e.g., IGBTs or MOSFETs, which are cooled by means of air or liquid cooling.

Additionally, some electrical components are sensitive to their external ambient temperature. For example, the operating lifetime of at least some electrical components is highly dependent on its operating temperature, which is limited to a relatively narrow range. However, such electrical components are installed in harsh environments where external temperatures can exceed the operating temperature of the electronics and also include high concentrations of air particulates. In such cases, the electrical components are packaged in a housing to protect them from the conditions of the outside environment. However, enclosing the electrical components within a housing may cause undesirable effects because of the heat dissipated by the electrical components. Thermal management of the electrical components is further affected not only due to the minimal temperature differential between the air within the housing and external air, but also because the electrical components should not be directly cooled by the particulate-laden external ambient air.

### BRIEF DESCRIPTION

In one aspect, an electrical system is provided. The electrical system includes a housing, a plurality of electrical components positioned within the housing, and a cooling system coupled in flow communication with the plurality of electrical components. The cooling system includes a sorption chiller positioned proximate the housing, wherein the cooling system is configured to utilize waste heat from the plurality of electrical components to condition air within the housing such that an internal temperature of the housing is less than an ambient temperature external to the housing.

In another aspect, a cooling system is provided. The cooling system includes a housing, a heat source, a first cooling subsystem configured to directly remove heat from the heat source, and a second cooling subsystem positioned within the housing. The second cooling subsystem is configured to condition air within the housing such that an internal temperature of the housing is less than an ambient temperature external to the housing. The cooling system also includes a sorption chiller positioned within the housing and coupled in flow communication with both the first cooling subsystem and the second cooling subsystem.

In another aspect, a method of assembling a cooling system is provided. The method includes positioning a heat source within a housing and coupling a first cooling system in flow communication with the heat source such that the first cooling system is configured to directly remove heat from the heat source. The method also includes coupling a second cooling system in flow communication with the heat source. The second cooling system is configured to condition air within the housing such that an internal temperature of the housing is less than an ambient temperature external to the housing. The method also includes positioning a sorption chiller proximate the housing and coupling the sorption chiller in flow communication with the first cooling system, the second cooling system, and the heat source.

### DRAWINGS

These and other features, aspects, and advantages of the present disclosure will become better understood when the following detailed description is read with reference to the accompanying drawings in which like characters represent like parts throughout the drawings, wherein:

FIG. 1 is a schematic view of an electrical device and associated electrical system; and

FIG. 2 is a schematic view of the electrical system shown in FIG. 1 and an exemplary cooling system for use with the electrical system.

Unless otherwise indicated, the drawings provided herein are meant to illustrate features of embodiments of this disclosure. These features are believed to be applicable in a wide variety of systems comprising one or more embodiments of this disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

Approximating language, as used herein throughout the specification and claims, is applied to modify any quantitative representation that could permissibly vary without resulting in a change in the basic function to which it is related. Accordingly, a value modified by a term or terms, such as “about”, “approximately”, and “substantially”, are not to be limited to the precise value specified. In at least some instances, the approximating language may correspond to the precision of an instrument for measuring the value. Here and throughout the specification and claims, range limitations are combined and interchanged; such ranges are identified and include all the sub-ranges contained therein unless context or language indicates otherwise.

Furthermore, as used herein, the term “sorption” describes a physical and chemical process by which one substance becomes attached to another. More specifically, “sorption” can be used to describe either adsorption or absorption. Absorption is the incorporation of a substance in one state into another of a different state (e.g., liquids being absorbed by a solid or gases being absorbed by a liquid. Adsorption is the physical adherence or bonding of ions and molecules onto the surface of another phase (e.g., reagents adsorbed to a solid catalyst surface).

The cooling systems described herein facilitate efficient methods of cooling electrical components for use in an electrical system that controls or powers an electrical device. The electrical system includes a housing, a plurality of electrical components positioned within the housing, and a cooling system coupled in flow communication with the plurality of electrical components. The cooling system includes a direct cooling subsystem, an indirect cooling subsystem, and a sorption chiller positioned proximate, and more specifically, within, the housing. As used herein, the term “direct” is meant to describe the cooling subsystem that directly interacts with the electrical components, that is, the system that channels a cooling fluid over the electrical components to transfer heat primarily by conduction and convection. Similarly, as used herein, the term “indirect” is meant to describe the cooling subsystem that indirectly interacts with the electrical components, that is, the system that effects the environment in which the electrical components are positioned mainly by convection and/or radiation.

The direct cooling subsystem channels a cooling fluid flow across the electrical components to facilitate cooling and then channels the heated fluid through the sorption chiller to desorb a desiccant material therein before channeling the cooled, but still hotter than ambient, fluid to a heat exchanger outside the housing for cooling by the ambient environment.

The indirect cooling system includes a heat exchanger positioned within the housing and configured to draw in air from within the housing heated by the electrical components. The indirect cooling system then channels cooling fluid from the sorption chiller to the internal heat exchanger to cool the heated internal air before the now cooled air is exhausted from the internal heat exchanger back into the housing interior. As such, the cooling system utilizes waste heat from the plurality of electrical components to condition air within the housing such that an internal temperature of the housing is less than an ambient temperature external to the housing.

Accordingly, the cooling systems described herein provide various technological advantages and/or improvements over existing cooling systems. The disclosed cooling system ensures operation of electrical components within predetermined operating conditions, extends the service lifetime of electrical components used in harsh environments, and reduces labor and materials cost of servicing and maintenance. As a result of the above, various embodiments of the present disclosure facilitate extended electrical component operating conditions, extending the life and/or maintenance intervals for various electrical components, and decreased cost in maintenance labor and materials.

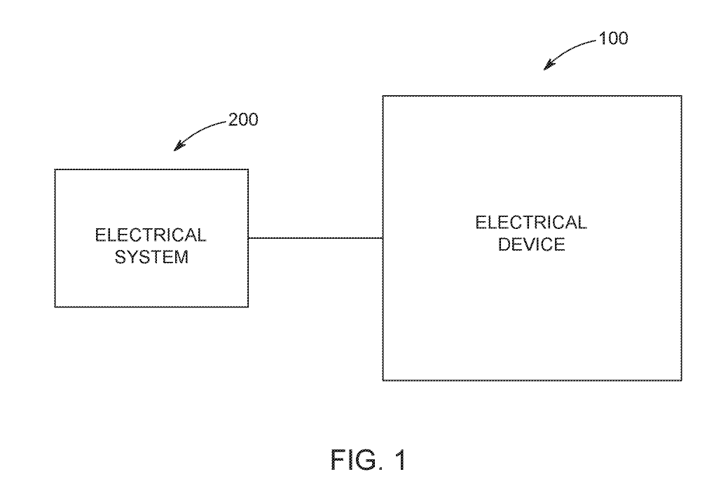

FIG. 1 is a schematic view of an electrical device 100 and associated electrical system 200 for use in electrical device 100. In the exemplary embodiment, electrical device 100 is any device powered by electrical power, such as by electrical system 200. More specifically, electrical system 200 includes electrical components (not shown in FIG. 1) that facilitate providing power to or controlling electrical device 100. For example, electrical system 200 includes electrical power converters that convert electrical energy, received from a power source (not shown), from one form to another, e.g., and without limitation, from AC to DC, or change the frequency or voltage. In the exemplary embodiment, electrical device 100 operates in an environment in which certain conditions may exceed operating limitations of electrical system 200. For example, electrical device 100 includes a device in an industry such as, but not limited to, solar energy, wind power, electric vehicles, or marine propulsion, where electrical device 100 is subject to relatively high temperatures or particulate concentrations that may exceed operating limitations of electrical system 200. As such, as described herein, electrical system 200 includes cooling and protection against particulates to maintain operation. Alternatively, electrical device 100 includes any device that operates using electrical power and electrical system 200 includes cooling for any reason to facilitate operation of electrical device as described herein.

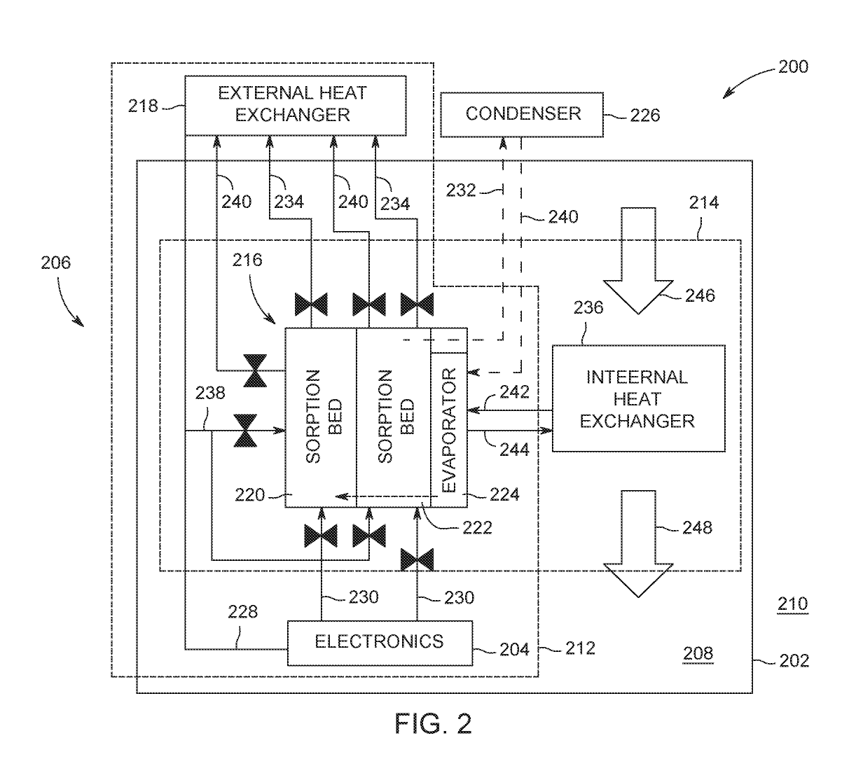

FIG. 2 is a schematic view of electrical system 200 that may be used with electrical device 100 (shown in FIG. 1). In the exemplary embodiment, electrical system 200 includes a housing 202, a plurality of electrical components 204, and a cooling system 206 to cool electrical components 204. Housing 202 defines an interior 208 in which electrical components 204 are positioned and separates electrical components 204 from an external environment 210 outside housing 202. In the exemplary embodiment, cooling system 206 includes a direct, or first, cooling subsystem 212 and an indirect, or second, cooling subsystem 214 that combine to provide simultaneous direct and indirect cooling to electrical components 204 within housing, as described in further detail below. More specifically, direct cooling subsystem 212 removes heat from electrical components 204 by channeling a relatively cold fluid (liquid or gas) proximate electrical components 204 to facilitate heat transfer to the cold fluid and reduce and maintain the temperature of the electrical components 204. Additionally, indirect cooling subsystem 214 utilizes waste heat from electronics components 204 to condition the air within interior 208 such that an internal temperature of interior is less than an external temperature of exterior environment 210. The temperature difference between interior 208 and exterior 210 facilitates cooling electrical components 204.

In the exemplary embodiment, cooling system 206 includes a sorption chiller 216 positioned within housing 202 and coupled in flow communication with both direct and indirect cooling subsystems 212 and 214. More specifically, sorption chiller 216 includes a first sorption bed 220 containing desiccant material, a second sorption bed 222 containing desiccant material, and an evaporator chamber 224. Additionally, cooling system 206 includes a condenser 226 positioned outside housing 202 in external environment 210 and coupled in flow communication with chiller 216. Sorption chiller 216 is operated at nearly a full vacuum and cycles first and second sorption beds 220 and 222, respectively, between adsorbing cycles. As shown in FIG. 2, cooling system 206 is shown in a first operating mode where first sorption bed 220 is in the sorption cycle and second sorption bed 222 is in the desorption cycle. Once the desiccant material in first sorption bed is saturated with water vapor, chiller 216 switches cycles such that, in a second operating mode, first sorption bed 220 is in the desorption cycle and second sorption bed 222 is in the sorption cycle.

In the exemplary embodiment, direct cooling subsystem 212 includes electrical components 204, sorption chiller 216, and an external heat exchanger 218 all coupled in flow communication with each other. External heat exchanger 218 is positioned outside housing 202 and is exposed to exterior environment 210. In the exemplary embodiment, external heat exchanger 218 channels a cooling fluid flow 228 to electrical components 204, which are subsequently cooled by the cooling flow 228. The now heated fluid flow 230 is at a temperature higher than the external temperature in environment 210 and is channeled to sorption chiller 216, where the otherwise wasted heat from electrical components 204 is utilized to desorb a desiccant material, such as, but not limited to, silica gel within chiller 216.

More specifically, in the first mode of operation, heated flow 230 is channeled to second sorption bed 222 to facilitate desorbing the desiccant material therein. A refrigerant vapor flow 232 from the desiccant material is heated by heated flow 230 and is channeled to condenser 226 outside housing 202 for cooling. Heated fluid flow 230 is partially cooled within chiller 216, but is still at a temperature higher than the external temperature in environment 210. As such, a second heated fluid flow 234, at a lower temperature than fluid flow 230, is channeled from chiller 216 to external heat exchanger 218. Heat exchanger 218 is exposed to the relatively cooler external environment 210 such that fluid flow 234 is cooled within heat exchanger 218 and is channeled back into housing 202 to cool electrical components 204.

In the first mode of operation, as direct cooling subsystem 212 channels fluid though second sorption bed 222, indirect cooling subsystem 214 channels fluid through first sorption bed 220. In the exemplary embodiment, indirect cooling subsystem 214 includes sorption chiller 216 and an internal heat exchanger 236 positioned within housing 202 and exposed to interior environment 208. Internal heat exchanger 236 draws in warm air from within housing interior 208, which has been warmed by heat dissipated by electrical components, and transfers the heat to a cooling fluid flow provided by chiller. Heat exchanger 236 then channels the cooled air into housing interior 208 to lower the temperature within interior 208 such that the temperature differential between interior and exterior 208 and 210 of housing 202 is increased.

More specifically, external heat exchanger 218 channels a cooling fluid flow 238 into first sorption bed 220 of chiller 216. Fluid flow 238 facilitates cooling the desiccant material undergoing sorption. The now heated fluid flow 240 is at a temperature higher than the external temperature in environment 210 and is channeled back to external heat exchanger 218 for cooling.

In the exemplary embodiment, condenser 226 condenses refrigerant vapor flow 232 from second sorption bed 222 into a liquid and channels a refrigerant liquid flow 240 into evaporator 224 of chiller 216. As chiller 216 operates at near or full vacuum, liquid flow 240 boils at the low pressure and flashes off surfaces of evaporator 224 into water vapor. This creates a chilling effect in evaporator 224 that chills a hot fluid flow 242 channeled to evaporator 224 from internal heat exchanger 236. Hot fluid flow 242 is cooled by the evaporative process occurring in evaporator 224, producing a cold fluid flow 244, which is output from evaporator 224 to internal heat exchanger 236. As described above, internal heat exchanger 236 draws in hot ambient air 246 from within housing interior 208. Heat is transferred from airflow 246 to cold fluid flow 244 within internal heat exchanger 236. In the exemplary embodiment, internal heat exchanger 236 then exhausts a cold airflow 248 to interior 208 of housing 202. As such, internal heat exchanger 236, and more generally, indirect cooling subsystem 214, facilitates conditioning the air within housing interior 208 to lower the temperature within housing 202 such that electrical components 204 are exposed to a relatively lower temperature and such that the temperature differential between interior and exterior 208 and 210 of housing 202 is increased.

As described above, when the desiccant material in sorption bed 220 is substantially saturated with water and the desiccant material in sorption bed 222 is substantially dry, chiller 216 automatically reverses, shifting sorption bed 220 into the desorption cycle and sorption bed 222 into the sorption cycle. The first step of this switch is to open a plurality of valves that control cooling flow 238 into sorption bed 222 and that control hot fluid flow 230 into sorption bed 220, thereby allowing the vapor pressure to equalize within chiller 216. Similarly, the corresponding valves that control flows 234 and 240 in chambers 220 and 222, respectively, are also opened. Then a plurality of valves that control cooling fluid flow 238 into chamber 220 and hot fluid flow 230 into chamber 222 are closed along with the corresponding valves that control flows 240 and 234 in chambers 220 and 222, respectively. As such, the flows of cooling water and hot water (or driving fluid) through sorption beds 220 and 222 are switched in order to begin the sorption and desorption cycles in those chambers 220 and 222.

Exemplary embodiments of a cooling system for cooling an electrical system for use in an electrical device are described in detail above. The electrical system includes a housing, a plurality of electrical components positioned within the housing, and a cooling system coupled in flow communication with the plurality of electrical components. The cooling system includes both a direct cooling subsystem, an indirect cooling subsystem, and a sorption chiller positioned within the housing. The direct cooling subsystem channels a cooling fluid flow across the electrical components to facilitate cooling and then channels the heated fluid through the sorption chiller to desorb a desiccant material therein before channeling the cooled, but still hotter than ambient, fluid to a heat exchanger outside the housing for cooling by the ambient environment. The indirect cooling system includes a heat exchanger positioned within the housing and configured to draw in air from within the housing heated by the electrical components. The indirect cooling system then channels cooling fluid from the sorption chiller to the internal heat exchanger to cool the heated internal air before the now cooled air is exhausted from the internal heat exchanger back into the housing interior. As such, the cooling system utilizes waste heat from the plurality of electrical components to condition air within the housing such that an internal temperature of the housing is less than an ambient temperature external to the housing.

An exemplary technical effect of the methods, systems, and apparatus described herein includes at least one of: (a) cooling electrical components of electrical systems to ensure operation within predetermined operating conditions; (b) extending the service lifetime of electrical components used in harsh environments; and (c) reducing the labor and materials cost of servicing and maintenance. As a result of the above, various embodiments of the present disclosure facilitate extended electrical component operating conditions, extending the life and/or maintenance intervals for various electrical components, and decreased cost in maintenance labor and materials.

Exemplary embodiments of methods, systems, and apparatus for a cooling system are not limited to the specific embodiments described herein, but rather, components of systems and steps of the methods may be utilized independently and separately from other components and steps described herein. For example, the methods may also be used in combination with other cooling systems, and are not limited to practice with only the electrical component system and methods as described herein. Rather, the exemplary embodiment can be implemented and utilized in connection with many other applications, equipment, and systems that may benefit from the advantages described herein.

Although specific features of various embodiments of the disclosure may be shown in some drawings and not in others, this is for convenience only. In accordance with the principles of the disclosure, any feature of a drawing may be referenced and claimed in combination with any feature of any other drawing.

This written description uses examples to disclose the embodiments, including the best mode, and also to enable any person skilled in the art to practice the embodiments, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. An electrical system for use in powering an electrical device, said electrical system comprising:
a housing;
a plurality of electrical components positioned within said housing; and
a cooling system coupled in flow communication with said plurality of electrical components, said cooling system comprising a sorption chiller positioned proximate said housing, wherein said cooling system is configured to utilize waste heat from said plurality of electrical components to condition air within said housing such that an internal temperature of said housing is less than an ambient temperature external to said housing.

2. The electrical system in accordance with claim 1, wherein said cooling system comprises a first heat exchanger coupled in flow communication with said sorption chiller, a condenser coupled in flow communication with said sorption chiller, and a second heat exchanger coupled in flow communication with said sorption chiller and coupled in flow communication with said plurality of electrical components.

3. The electrical system in accordance with claim 2, wherein said first heat exchanger is positioned within said housing.

4. The electrical system in accordance with claim 3, wherein said second heat exchanger is positioned outside said housing.

5. The electrical system in accordance with claim 2, wherein said condenser is positioned outside said housing.

6. The electrical system in accordance with claim 2, wherein said sorption chiller comprises:
a first sorption bed;
a second sorption bed, wherein said first sorption bed and said second sorption bed are coupled in flow communication with said second heat exchanger, said condenser, and said plurality of electrical components; and
an evaporator coupled in flow communication with said first heat exchanger and coupled in flow communication with said condenser.

7. The electrical system in accordance with claim 6, wherein said first sorption bed is configured to receive a cooling fluid flow from said second heat exchanger in a first mode of operation, said first sorption bed is further configured to receive a hot fluid flow from said plurality of electrical components in a second mode of operation.

8. The electrical system in accordance with claim 7, wherein said second sorption bed is configured to receive a hot fluid flow from said plurality of electrical components in the first mode of operation, said second sorption bed is further configured to receive a cooling fluid flow from said second heat exchanger in a second mode of operation.

9. The electrical system in accordance with claim 8, wherein said evaporator is configured to receive a hot fluid flow from said first heat exchanger in both the first and second modes of operation.

10. A cooling system comprising:
a housing;
a heat source;
a first cooling subsystem configured to remove heat from said heat source;
a second cooling subsystem positioned within said housing and configured to condition air within said housing such that an internal temperature of said housing is less than an ambient temperature external to said housing; and
a sorption chiller positioned within said housing and coupled in flow communication with both said first cooling subsystem and said second cooling subsystem.

11. The cooling system in accordance with claim 10, wherein said first cooling subsystem comprises a first heat exchanger coupled in flow communication with said heat source and positioned outside said housing, and wherein said second cooling subsystem comprises a second heat exchanger coupled in flow communication with said heat source, said second heat exchanger positioned inside said housing.

12. The cooling system in accordance with claim 11, wherein said second cooling subsystem is configured to utilize waste heat from said heat source to provide said second heat exchanger with a cooling air flow.

13. The cooling system in accordance with claim 10, wherein said first cooling subsystem comprises a first heat exchanger coupled in flow communication with said sorption chiller, said first heat exchanger positioned outside said housing, and wherein said second cooling subsystem comprises a second heat exchanger coupled in flow communication with said sorption chiller, said second heat exchanger positioned within said housing.

14. The cooling system in accordance with claim 13 further comprising a condenser coupled in flow communication with said sorption chiller, said condenser positioned outside said housing.

15. The cooling system in accordance with claim 14, wherein said sorption chiller comprises:
a first sorption bed;
a second sorption bed, wherein said first and said second sorption beds are coupled in flow communication with said second heat exchanger, said condenser, and said heat source; and
an evaporator coupled in flow communication with said first heat exchanger and said condenser.

16. The cooling system in accordance with claim 15,
wherein said first sorption bed is configured to receive a cooling fluid flow from said first heat exchanger in a first mode of operation, said first sorption bed is configured to receive a hot fluid flow from said heat source in a second mode of operation;
wherein said second sorption bed is configured to receive a hot fluid flow from said heat source in the first mode of operation, said second sorption bed is configured to receive a cooling fluid flow from said first heat exchanger in a second mode of operation; and
wherein said evaporator is configured to receive a hot fluid flow from said second heat exchanger in both the first and second modes of operation.

17. A method of assembling a cooling system, said method comprising:
positioning a heat source within a housing;
coupling a first cooling system in flow communication with the heat source, wherein the first cooling system is configured to remove heat from the heat source;
coupling a second cooling system in flow communication with the heat source, wherein the second cooling system is configured to condition air within the housing such that an internal temperature of the housing is less than an ambient temperature external to the housing; and
positioning a sorption chiller proximate the housing and coupling the sorption chiller in flow communication with the first cooling system, the second cooling system, and the heat source.

18. The method in accordance with claim 17, wherein coupling a first cooling system comprises positioning a first heat exchanger outside the housing and coupling the first heat exchanger in flow communication with the heat source and the sorption chiller, and wherein coupling a second cooling system comprises positioning a second heat exchanger within the housing and coupling the second heat exchanger in flow communication with the sorption chiller.

19. The method in accordance with claim 18, wherein coupling the sorption chiller in flow communication with the first cooling system, the second cooling system, and the heat source comprises:
coupling a first sorption bed of the sorption chiller in flow communication with the first heat exchanger such that the first sorption bed receives a cooling flow from the first heat exchanger in a first mode of operation;
coupling the first sorption bed of the sorption chiller in flow communication with the heat source such that the first sorption bed receives a hot fluid flow from the heat source in a second mode of operation;
coupling a second sorption bed of the sorption chiller in flow communication with the heat source such that the second sorption bed receives a hot fluid flow from the heat source in the first mode of operation; and
coupling the second sorption bed of the sorption chiller in flow communication with the first heat exchanger such that the first sorption bed receives a cooling fluid flow from the first heat exchanger in the second mode of operation.

20. The method in accordance with claim 19, further comprising coupling an evaporator of the sorption chiller in flow communication with the second heat exchanger such that the evaporator receives a hot fluid flow from the second heat exchanger in both the first and second modes of operation.
